(19) United States
(12) Patent Application Publication
(10) Pub. No.: US 2026/0015721 A1
(43) Pub. Date: Jan. 15, 2026

(54) FILM FORMATION METHOD AND FILM FORMATION APPARATUS

(71) Applicant: TOKYO ELECTRON LIMITED, Tokyo (JP)

(72) Inventor: Sena FUJITA, Nirasaki City (JP)

(21) Appl. No.: 19/278,171

(22) Filed: Jul. 23, 2025

Related U.S. Application Data
(63) Continuation of application No. PCT/JP2024/000903, filed on Jan. 16, 2024.

(30) Foreign Application Priority Data
Jan. 27, 2023 (JP) 2023-010862

(51) Int. Cl. C23C 16/455; C23C 16/02; C23C 16/04; C23C 16/44; C23C 16/458; C23C 16/52

(52) U.S. Cl. CPC C23C 16/45553; C23C 16/0236; C23C 16/045; C23C 16/4401; C23C 16/45544; C23C 16/458; C23C 16/52

(57) ABSTRACT

A film formation method includes: preparing a substrate having a first film and a second film made of a material different from the first film in different regions of a surface of the substrate; supplying a cleaning gas to the surface to remove an organic compound; selectively forming a third film on the second film with respect to the first film from which the organic compound has been removed; and protecting the surface in at least one of a vacuum atmosphere or an inert atmosphere from immediately after removing the organic compound to immediately before forming the third film without exposing the surface of the substrate to an air atmosphere. The forming the third film includes forming the third film containing an element by alternately or simultaneously supplying a raw material gas and a reaction gas reacting with raw material gas to the surface of the substrate.

### CROSS-REFERENCE TO RELATED APPLICATIONS

This application is a bypass continuation application of International Application No. PCT/JP2024/000903 having an international filing date of Jan. 16, 2024 and designating the United States, the international application being based upon and claiming the benefit of priority from Japanese Patent Application No. 2023-010862, filed on Jan. 27, 2023, the entire contents of which are incorporated herein by reference.

### TECHNICAL FIELD

The present disclosure relates to a film formation method and a film formation apparatus.

### BACKGROUND

A nitride film forming method disclosed in Patent Document 1 includes adsorbing a chlorine gas onto surfaces of a first underlying film and a second underlying film, and selectively forming a nitride film on one of the first underlying film and the second underlying film onto which the chlorine gas has been adsorbed.

### PRIOR ART DOCUMENT

### Patent Document

Patent Document 1: Japanese Laid-Open Patent Publication No. 2017-174919

### SUMMARY

According to one embodiment of the present disclosure, a film formation method includes: preparing a substrate having a first film containing boron and a second film made of a material different from a material of the first film in different regions of a surface of the substrate; supplying a cleaning gas to the surface of the substrate to remove an organic compound; selectively forming a third film on the second film with respect to the first film from which the organic compound has been removed; and protecting the surface of the substrate in at least one of a vacuum atmosphere or an inert atmosphere from immediately after removing the organic compound to immediately before forming the third film without exposing the surface of the substrate to an air atmosphere, wherein the forming the third film includes forming the third film containing an element by alternately or simultaneously supplying a raw material gas, which contains halogen and the element other than the halogen, and a reaction gas, which reacts with an adsorbate of the raw material gas, to the surface of the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film formation method according to an embodiment.

FIG. 2 is a flowchart illustrating an example of an operation illustrated in FIG. 1.

FIG. 3 is a flowchart illustrating a modified example of the operation illustrated in FIG. 1.

FIG. 4 is a flowchart illustrating another modified example of the operation illustrated in FIG. 1.

FIG. 5 is a cross-sectional view illustrating a first example of the film formation method.

FIG. 6 is a cross-sectional view illustrating a second example of the film formation method.

FIG. 7 is a cross-sectional view illustrating a third example of the film formation method.

FIG. 8 is a cross-sectional view illustrating a fourth example of the film formation method.

FIG. 9 is a cross-sectional view illustrating a fifth example of the film formation method.

FIG. 10 is a cross-sectional view illustrating a sixth example of the film formation method.

FIG. 11 is a cross-sectional view illustrating a seventh example of the film formation method.

FIG. 12 is a cross-sectional view illustrating an eighth example of the film formation method.

FIG. 13 is a cross-sectional view illustrating a ninth example of the film formation method.

FIG. 14 is a flowchart illustrating a film formation method according to Modification.

FIG. 15 is a flowchart illustrating an example of an operation illustrated in FIG. 14.

FIG. 16 is a cross-sectional view illustrating a tenth example of the film formation method.

FIG. 17 is a cross-sectional view illustrating an eleventh example of the film formation method.

FIG. 18 is a cross-sectional view illustrating a film formation apparatus according to an embodiment.

FIG. 19 is a cross-sectional view illustrating an example of a first processor.

FIG. 20 is an SEM photograph illustrating a substrate before processing of Example 1.

FIG. 21 is an SEM photograph illustrating a substrate after processing of Example 1.

FIG. 22 is an SEM photograph illustrating a substrate after processing of Comparative Example 2.

FIG. 23 is an SEM photograph illustrating a substrate after processing of Comparative Example 3.

FIG. 24 is an SEM photograph illustrating a substrate after processing of Example 4.

FIG. 25 is an SEM photograph illustrating a substrate after processing of Comparative Example 5.

FIG. 26 is an SEM photograph illustrating a substrate after processing of Comparative Example 6.

FIG. 27 is an SEM photograph illustrating a substrate before processing of Example 7.

FIG. 28 is an SEM photograph illustrating a substrate after processing of Example 7.

FIG. 29 is an SEM photograph illustrating a substrate after processing of Comparative Example 8.

FIG. 30 is an SEM photograph illustrating a substrate after processing of Example 9.

FIG. 31 is an SEM photograph illustrating a substrate after processing of Comparative Example 10.

### DETAILED DESCRIPTION

Hereinafter, embodiments of the present disclosure will be described with reference to the drawings. In each of the drawings, the same or corresponding parts will be denoted by the same reference numerals, and redundant descriptions thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

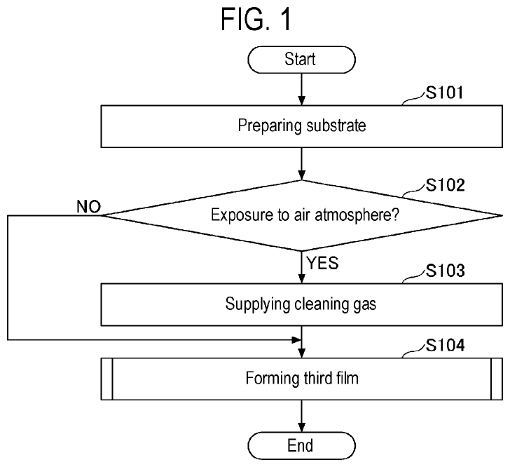

First, a film formation method according to an embodiment will be described with reference to FIG. 1. The film formation method includes, for example, Operations S101 to S104 illustrated in FIG. 1. The film formation method may include at least Operations S102 to S104. Alternatively, the film formation method may include operations other than Operations S101 to S104 illustrated in FIG. 1.

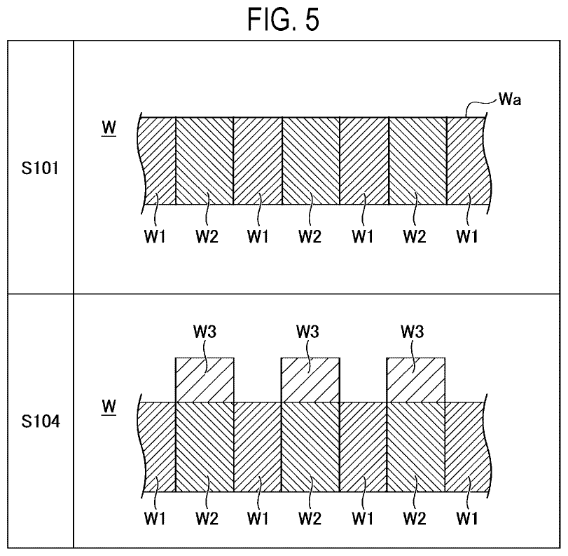

Operation S101 includes preparing a substrate W (for example, see FIG. 5). The substrate W has a first film W1 containing boron (B) and a second film W2 made of a material different from that of the first film W1 in different regions of a surface Wa. The first film W1 and the second film W2 are formed on, for example, an underlying substrate which is not illustrated. The underlying substrate is a silicon wafer or a compound semiconductor wafer. The compound semiconductor wafer is, for example, a GaAs wafer, a SiC wafer, a GaN wafer, or an InP wafer.

The first film W1 contains boron (B). A content of B in the first film W1 is, for example, 20 atomic % to 100 atomic %, specifically, 40 atomic % to 100 atomic %. The first film W1 is, for example, a B film, a BN film, a BNC film, a BO film, a BNOC film, a SiBN film, a SiBCN film, or a SiOBN film. Here, the BN film means a film containing boron (B) and nitrogen (N). An atomic ratio of B to N in the BN film is not limited to 1:1. Similarly, the BNC film or the like, other than the BN film, also means a film that contains constituent elements and is not limited to a specific stoichiometric ratio.

The second film W2 is made of a material different from that of the first film W1. The second film W2 contains substantially no B. The expression “contains substantially no B” means that the content of B is 0 atomic % to 5 atomic %. It is more desirable that the content of B in the second film W2 be small. The second film W2 may be any one of an insulating film, a conductive film, and a semiconductor film.

The insulating film as the second film W2 is not particularly limited but is, for example, a SiO film, a SiN film, a SiOC film, a SiON film, a SiOCN film, an AlO film, a ZrO film, a HfO film, or a TiO film. Here, the SiO film means a film containing silicon (Si) and oxygen (O). An atomic ratio of Si to O in the SiO film is generally 1:2 but is not limited to 1:2. Similarly, the SiN film, the SiOC film, the SiON film, the SiOCN film, the AlO film, the ZrO film, the HfO film, and the TiO film mean films containing constituent elements and are not limited to a specific stoichiometric ratio. The insulating film is, for example, an interlayer insulating film. The interlayer insulating film may be a low dielectric constant (low-k) film.

The semiconductor film as the second film W2 is not particularly limited but is, for example, a Si film, a SiGe film, or a GaN film. The semiconductor film may be any one of a monocrystalline film, a polycrystalline film, and an amorphous film.

The conductive film as the second film W2 is, for example, a metal film. The metal film is not particularly limited but is, for example, a Cu film, a Co film, a Ru film, a Mo film, a W film, or a Ti film. The conductive film may also be a metal nitride film. The metal nitride film is not particularly limited but is, for example, a TiN film or a TaN film. Here, the TiN film means a film containing titanium (Ti) and nitrogen (N). An atomic ratio of Ti to N in the TiN film is generally 1:1 but is not limited to 1:1. Similarly, the TaN film means a film containing constituent elements and is not limited to a specific stoichiometric ratio.

Operation S102 includes determining whether or not the surface Wa of the substrate W after forming the first film W1 has been exposed to an air atmosphere. Hereinafter, the surface Wa of the substrate W may sometimes be referred to as a substrate surface Wa. When the substrate surface Wa is exposed to the air atmosphere, the substrate surface Wa may be contaminated by an organic compound contained in the air atmosphere (for example, the organic compound may adhere to the substrate surface Wa and cover the substrate surface Wa). This may reduce the effect of the first film W1 containing boron (effect of the first film W1 which inhibits forming a third film W3 as will be described below).

In this specification, the air atmosphere is an atmosphere in which pressure is atmospheric pressure (about 101 kPa) and the content of air is of 95 vol % to 100 vol %. An inert atmosphere is an atmosphere in which the content of air is 5 vol % or less and the content of an inert gas is of 95 vol % to 100 vol % (specifically, 98 vol % to 100 vol %). The inert gas is composed of at least one selected from a N₂ gas and a noble gas (for example, an argon gas or a helium gas). The pressure of the inert atmosphere is not particularly limited but is, for example, atmospheric pressure. The inert gas is a gas, purity of which is controlled, and is supplied from, for example, a cylinder or the like.

In addition, in this specification, a vacuum atmosphere is an atmosphere having a pressure of 0 Pa to 10 kPa (specifically 0 Pa to 1 kPa). The vacuum atmosphere may include at least one selected from air, an inert gas, a hydrogen gas, and an ammonia gas. The vacuum atmosphere may be an atmosphere in which the air pressure is reduced to 10 kPa or less. By removing 90% or more of the air, most of organic compounds contained in the air may be removed. However, the vacuum atmosphere may be an atmosphere in which the inert atmosphere is reduced to 10,000 Pa or less from the atmospheric pressure. Gases other than the air (for example, an inert gas, a hydrogen gas, and an ammonia gas) are gases, purity of which is controlled, and are supplied from, for example, a cylinder or the like.

The film formation method may have a process of protecting the substrate surface Wa in at least one of the vacuum atmosphere or the inert atmosphere without exposing the substrate surface Wa to the air atmosphere from immediately after forming the first film W1 to immediately before forming the third film W3 (immediately before Operation S104). When the substrate surface Wa is not exposed to the air atmosphere (“NO” in Operation S102), the substrate surface Wa is not contaminated by an organic compound, and the effect of the first film W1 containing boron is not reduced. Thus, Operation S103 is not performed and Operation S104 is performed.

On the other hand, when the substrate surface Wa of the substrate W is exposed to the air atmosphere after forming the first film W1 (“YES” in Operation S102), the substrate surface Wa is contaminated by the organic compound, and the effect of the first film W1 containing boron (effect of the first film W1 inhibiting the formation of the third film W3 as described later) is reduced. Thus, Operation S103 is performed to remove the organic compound.

Operation S103 includes supplying a cleaning gas to the substrate surface Wa to remove the organic compound. As the cleaning gas, an oxygen-containing gas, a nitrogen-containing gas, or a hydrogen-containing gas may be used. The oxygen-containing gas is a gas containing oxygen, for example, an O₂ gas, an O₃ gas, a CO₂ gas, a N₂O gas, a NO gas, or a H₂O gas. The nitrogen-containing gas is a gas containing nitrogen, for example, a N₂ gas, a NH₃ gas, or a N₂H₄ gas. The hydrogen-containing gas is a gas containing hydrogen, for example, a H₂ gas or a H₂S gas. The cleaning gas may be a noble gas such as an Ar gas when plasma is formed as described below.

Operation S103 may include plasmarizing the cleaning gas or include supplying the plasmarized cleaning gas to the substrate surface Wa. When plasmarizing the cleaning gas, ions or radicals are generated. The generated ions or radicals collide with the substrate surface Wa, so that the organic compound is physically knocked away. When the cleaning gas is the oxygen-containing gas or the hydrogen-containing gas, the generated ions or radicals chemically react with the organic compound, so that the organic compound is decomposed into CO₂, CH₄, or the like and removed.

Operation S103 may include supplying the oxygen-containing gas (for example, the O₃ gas) or the hydrogen-containing gas (for example, the H₂ gas) as the cleaning gas to the substrate surface Wa without plasmarizing the cleaning gas. The oxygen-containing gas or the hydrogen-containing gas chemically reacts with the organic compound, so that the organic compound is decomposed into CO₂, CH₄, or the like and removed.

The cleaning gas is selected according to the material of the first film W1 or the material of the second film W2. For example, when the second film W2 is a metal film, an inert gas, such as a noble gas or a N₂ gas, or a reducing gas, such as a H₂ gas, may be used as the cleaning gas to prevent oxidation or nitridation of the metal film.

The film formation method includes protecting the substrate surface Wa in at least one of the vacuum atmosphere or the inert atmosphere, without exposing the substrate surface Wa to the air atmosphere, from immediately after the removal of the organic compound (immediately after Operation S103) to immediately before the formation of the third film W3 (immediately before Operation S104). As a result, it is possible to suppress recontamination of the substrate surface Wa by the organic compound again.

Operation S104 includes selectively forming a third film W3 on the second film W2 with respect to the first film W1 (see FIG. 5 or the like). Operation S104 includes forming the third film W3 containing an element X by alternately or simultaneously supplying a raw material gas, which contains halogen and the element X other than the halogen, and a reaction gas, which reacts with an adsorbate of the raw material gas, to the substrate surface Wa.

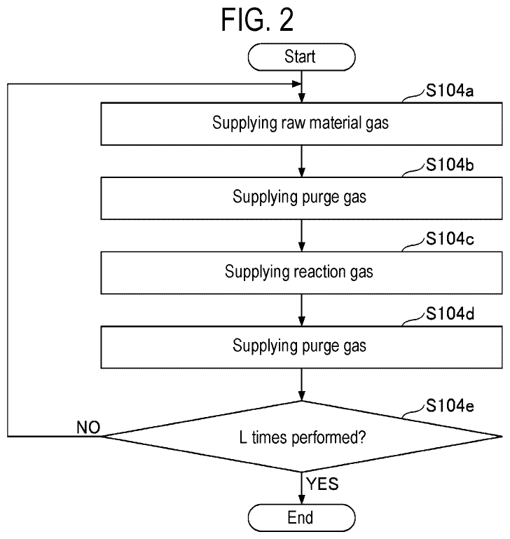

Operation S104 includes, for example, Operations S104a to S104e, as illustrated in FIG. 2. In addition, Operation S104 may include Operations S104a and S104c and may not have Operations S104b, S104d, and S104e. Hereinafter, Operations S104a to S104e will be described.

Operation S104a includes supplying the raw material gas to the substrate surface Wa. The raw material gas contains the halogen and the element X other than the halogen. The halogen is fluorine, chlorine, bromine, or iodine. The element X is not particularly limited but may be a metal element, and more specifically, a transition metal element. The element X is, for example, Ti, W, V, Al, Mo, Sn, Hf, Ta, Nb, Zr, In, Ga, or Sb. A specific example of the raw material gas may include a TiCl₄ gas, a WCl₆ gas, a WF₆ gas, a VCl₄ gas, an AlCl₃ gas, a MoCl₅ gas, a SnCl₄ gas, a HfCl₄ gas, a TaCl₅ gas, a NbCl₅ gas, a ZrCl₄ gas, an InCl₃ gas, a GaCl₃ gas, or a SbCl₃ gas. The element X may be a semiconductor element and, specifically, be Si or Ge. The raw material gas is a silicon halide gas or a germanium halide gas. A specific example of the silicon halide gas may include a SiCl₄ gas, a SiHCl₃ gas, a SiH₂Cl₂ gas, a SiH₃Cl gas, a Si₂Cl₆ gas, a Si₂HCl₅ gas, a Si₂Cl₃CH₃ gas, a SiCl₃CCl₃ gas, a SiCl₃CH₃ gas, or a SiH₂I₂ gas. A specific example of the germanium halide gas may include a GeCl₄ gas. The raw material gas may be supplied together with a dilution gas. The dilution gas is, for example, an Ar gas or a N₂ gas.

Operation S104b includes supplying a purge gas to the substrate surface Wa. The purge gas purges an excessive raw material gas that has not been adsorbed onto the substrate surface Wa in Operation S104a. As the purge gas, for example, a N₂ gas or a noble gas such as an Ar gas may be used.

Operation S104c includes supplying a reaction gas to the substrate surface Wa. The reaction gas forms the third film W3 containing the element X by reacting with the element X included in the adsorbate of the raw material gas. An example of the reaction gas may include an oxygen-containing gas, a nitrogen-containing gas, or a hydrogen-containing gas. The oxygen-containing gas contains oxygen and forms an oxide film of the element X. The oxygen-containing gas is, for example, an O₂ gas, an O₃ gas, a CO₂ gas, a N₂O gas, a NO gas, or a H₂O gas. The nitrogen-containing gas contains nitrogen and forms a nitride film of the element X. The nitrogen-containing gas is, for example, a NH₃ gas or a N₂H₄ gas. The hydrogen-containing gas contains hydrogen and forms a film (for example, a metal film or a semiconductor film) mainly composed of the element X. The hydrogen-containing gas is, for example, a H₂ gas or a H₂S gas. The reaction gas may be supplied together with the dilution gas. The dilution gas is, for example, an Ar gas or a N₂ gas.

Operation S104c may include plasmarizing the reaction gas and may further include supplying the plasmarized reaction gas to the substrate surface Wa.

Alternatively, the reaction gas may be supplied not only in Operation S104c, but also in all of Operations S104a to S104d. However, the plasmarization of the reaction gas is performed only in Operation S104c. This is because the reaction gas becomes more likely to react with the adsorbate of the raw material gas on the substrate surface Wa by being plasmarized.

Operation S104c may further include supplying an O₃ gas as the reaction gas to the substrate surface Wa without plasmarization. Even in this case, it is possible to remove the organic compound adhering to the substrate surface Wa during Operation S104, similarly to Operation S103. However, according to the present embodiment, since the substrate surface Wa is clean, the type of the reaction gas is not particularly limited.

Operation S104d includes supplying the purge gas to the substrate surface Wa. The purge gas purges an excessive reaction gas that has not reacted with the substrate surface Wa in Operation S104c. As the purge gas, for example, a N₂ gas or a noble gas such as an Ar gas may be used.

In Operation S104e, whether or not Operations S104a to S104d have been performed L times (where L is an integer equal to or greater than 1) is determined. L may be an integer equal to or greater than 2, and Operations S104a to S104d may be repeatedly performed. A film thickness of the third film W3 may be increased.

When it is determined that the execution number of times of Operations S104a to S104d is less than L times (“NO” in Operation S104e), the film thickness of the third film W3 is less than a target value. Thus, Operations S104a to S104d are performed again. L may be 200 or more, more specifically 300 or more. L may be 1,000 or less.

On the other hand, when it is determined that the execution number of times of Operations S104a to S104d reaches L times (“YES” in Operation S104e), the film thickness of the third film W3 reaches the target value. Thus, Operation S104 ends.

The method of forming the third film W3 illustrated in FIG. 2 is an atomic layer deposition (ALD) method but may also be a chemical vapor deposition (CVD) method. In the ALD method, the supply of the raw material gas (Operation S104a) and the supply of the reaction gas (Operation S104c) are alternately performed. On the other hand, in the CVD method, the supply of the raw material gas and the supply of the reaction gas are simultaneously performed.

In order to inhibit the formation of the third film W3 on the surface of the first film W1, it is important that the raw material gas be weakly adsorbed onto the first film W1 or not be adsorbed, and consequently, the adsorbate of the raw material gas on the surface of the first film W1 be desorbed without performing film formation reaction (the formation of the third film W3). Alternatively, it is important that adsorption of the raw material gas onto the surface of the first film W1 not occur or that dissociation of the raw material gas be unlikely to occur on the surface of the first film W1. When the dissociation of the raw material gas occurs, the film formation reaction is likely to proceed.

Since the first film W1 contains boron and since the surface thereof is exposed without being covered by the organic compound, it is considered that adsorption of the halide on the first film W1 does not occur or occurs weakly, or dissociation of the halide is unlikely to occur. As a result, the formation of the third film W3 on the surface of the first film W1 is inhibited.

On the other hand, since the second film W2 contains substantially no boron, it is considered that the halide is strongly adsorbed onto the second film W2 or the dissociation of the halide is likely to occur. As a result, it is considered that the formation of the third film W3 proceeds on the surface of the second film W2.

In addition, even in the case where the first film W1 contains boron, when the organic material contained in the air covers and hides the surface of the first film W1, the inhibition of adsorption of the halides by boron is unlikely to occur, and the raw material gas is adsorbed onto the organic compound. The raw material gas adsorbed onto the organic compound reacts with the reaction gas supplied in Operation S104c, and the third film W3 is formed on the first film W1 as well.

However, in Operation S104c, when the oxygen-containing gas is supplied to the substrate surface Wa as the reaction gas, there are cases in which the organic compound adhering to the substrate surface Wa may be removed, as in Operation S103.

In addition, the halide such as TiCl₄ is less likely to be decomposed by the heat of the substrate W compared to an organometallic complex such as Ti[N(CH₃)₂]₄. When the raw material gas is decomposed after being adsorbed onto the first film W1, the formation of the third film W3 proceeds. Therefore, in order to inhibit the formation of the third film W3 on the surface of the first film W1, a gas containing halogen is appropriate as the raw material gas of the third film W3.

In addition, in the plasma CVD method of plasmarizing both the halide and the reaction gas, active species such as ions or radicals generated by the dissociation of the halide are generated. It is considered that the active species generated from the halide has high reactivity and that the film formation reaction easily proceeds not only on the surface of the second film W2 but also on the surface of the first film W1. Therefore, it is desirable not to plasmarize the raw material gas and it is important to use a thermal ALD method, a plasma ALD method, or a thermal CVD method.

In Operations S104a to S104d described above, the temperature of the substrate W may be controlled to 100 degrees C. or higher in order to promote the desorption of the raw material gas from the surface of the first film W1. When the temperature of the substrate W is less than 100 degrees C., the raw material gas is physically adsorbed onto the surface of the first film W1 without being sufficiently desorbed from the surface of the first film W1. As a result, the third film W3 may be formed even on the surface of the first film W1. The temperature of the substrate W may be 300 degrees C. or higher. Specifically, the temperature of the substrate W may be 800 degrees C. or lower.

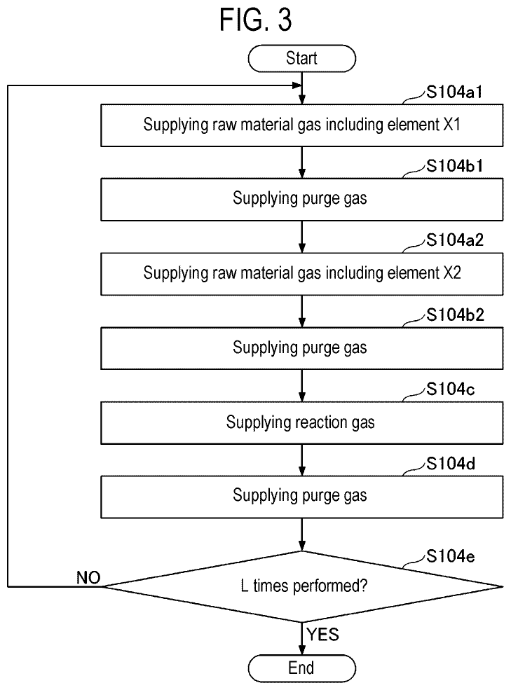

Next, a modified example of Operation S104 will be described with reference to FIG. 3. Hereinafter, differences from Operation S104 will be mainly described. Operation S104 includes performing, one or more times, a process of sequentially supplying a raw material gas including an element X1 as the element X (Operation S104a1), supplying a raw material gas including an element X2 different from the element X1 as the element X (Operation S104a2), and supplying a reaction gas that reacts with an adsorbate of the raw material gas (Operation S104c).

Alternatively, an operation of supplying a purge gas (Operation S104b1) may be performed between Operations S104a1 and S104a2. Further, an operation of supplying the purge gas step (Operation S104b2) may be performed between Operations S104a2 and S104c.

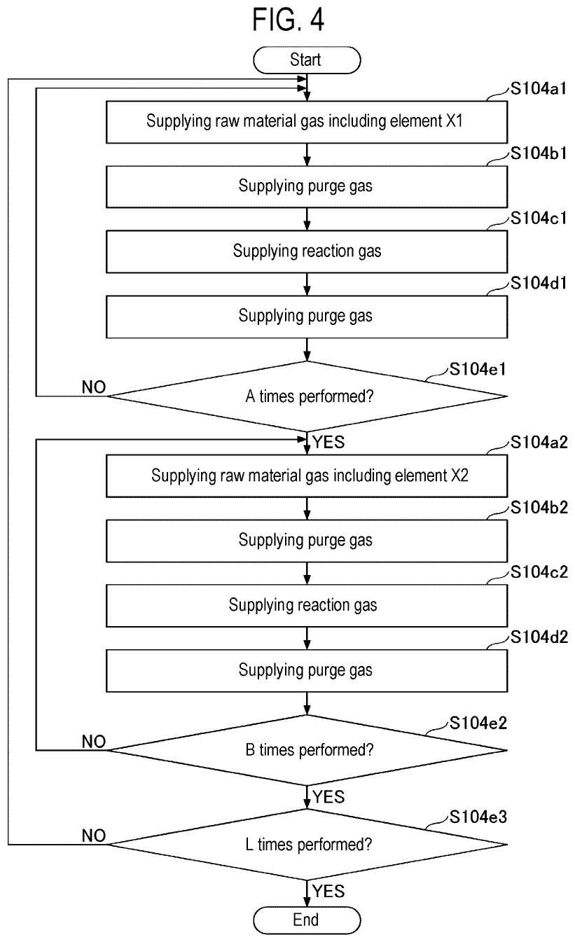

Next, another modified example of Operation S104 will be described with reference to FIG. 4. Hereinafter, differences from Operation S104 will be mainly described. As illustrated in FIG. 4, Operation S104 includes performing, one or more times, a process of sequentially supplying a raw material gas containing the element X1 as the element X (Operation S104a1) and supplying a reaction gas reacting with an adsorbate of the raw material gas (Operation S104c1). In addition, Operation S104 includes performing, one or more times, a process of sequentially supplying a raw material gas containing the element X2 different from the element X1 as the element X (Operation S104a2) and supplying the reaction gas reacting with the adsorbate of the raw material gas (Operation S104c2).

In Operation S104e1 of FIG. 4, A may be an integer equal to or greater than 1 or may be an integer equal to or greater than 2. When A is an integer equal to or greater than 2, Operations S104a1, S104b1, S104c1, and S104d1 are repeatedly performed multiple times. In Operation S104e2 of FIG. 4, B may be an integer equal to or greater than 1 or may be an integer equal to or greater than 2. When B is an integer equal to or greater than 2, Operations S104a2, S104b2, S104c2, and S104d2 are repeatedly performed multiple times.

Alternatively, an operation of supplying a purge gas (Operation S104b1) may be performed between Operations S104a1 and S104c1. Further, an operation of supplying the purge gas (Operation S104d1) may be performed immediately after Operation S104c1. Moreover, an operation of supplying the purge gas (Operation S104b2) may be performed between Operations S104a2 and S104c2. In addition, an operation of supplying the purge gas (Operation S104d2) may be performed immediately after Operation S104c2.

In FIGS. 3 and 4, one of the elements X1 and X2 is a metal element (specifically, a transition metal element), and the other is a semiconductor element. In FIGS. 3 and 4, the combination of the element X1 and the element X2 is not particularly limited. The combination of the element X1 and the element X2 may be a combination of metal elements or a combination of semiconductor elements. In any case, the third film W3 including the element X1 and the element X2 is obtained. The element X may include an element X3 different from the element X1 and the element X2 or may include three or more different elements. An operation of supplying a raw material gas including the element X3 may be performed.

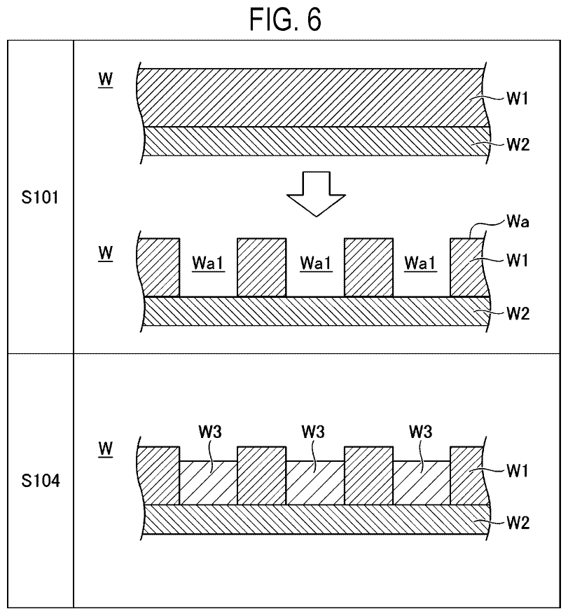

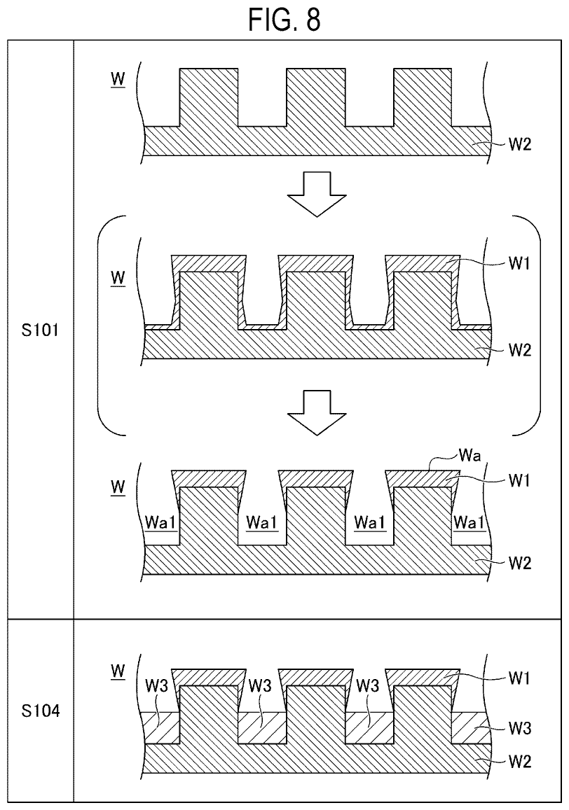

Next, descriptions of the case where the substrate W prepared in Operation S101 has a recess Wa1 on the substrate surface Wa, and the second film W2 is exposed only inside the recess Wa1 will be given with reference to FIGS. 6 to 8. As illustrated in FIGS. 6 to 8, the second film W2 is exposed at least on a bottom surface of the recess Wa1. In this case, by performing Operation S102 and subsequent operations, the interior of the recess Wa1 may be filled with the third film W3. In FIGS. 6 to 8, the recess Wa1 may be partially or entirely filled with the recess Wa1. In the case where the recess Wa1 is entirely filled with the recess Wa1, in FIG. 8, the first film W1 may be left only on a top surface of a protrusion of the second film W2 by etching.

In Operation S101 of FIG. 6, first, the first film W1 is formed on the entire surface of the second film W2, and then a portion of the surface of the first film W1 is etched. As a result, the recess Wa1 is formed to penetrate a portion of the first film W1, and the second film W2 is exposed only on a bottom surface of the recess Wa1. Thereafter, by performing Operation S102 and subsequent operations, the third film W3 grows only on the bottom surface of the recess Wa1.

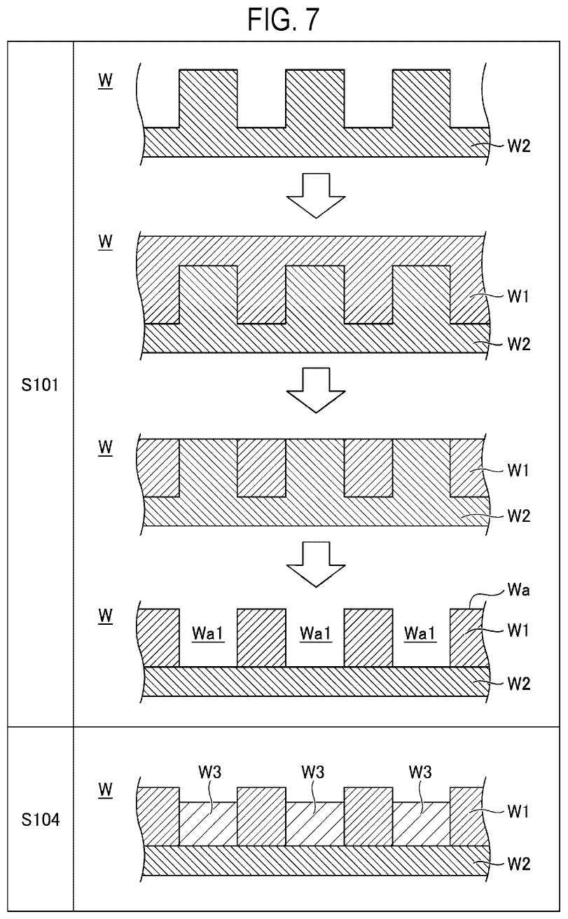

In Operation S101 of FIG. 7, first, a portion of the surface of the second film W2 is etched to form a recess on the surface of the second film W2. Next, the first film W1 is formed to fill the recess. Next, the first film W1 is processed by CMP or etching until the second film W2 is exposed. Lastly, the second film W2 is selectively etched with respect to the first film W1. As a result, the recess Wa1 is formed to penetrate a portion of the first film W1, and the second film W2 is exposed only on the bottom surface of the recess Wa1. Thereafter, by performing Operation S102 and subsequent operations, the third film W3 grows only on the bottom surface of the recess Wa1.

In Operation S101 of FIG. 8, first, a portion of the surface of the second film W2 is etched to form a recess on the surface of the second film W2. Next, the first film W1 is selectively formed on the outside of the recess (that is, a top surface of the protrusion) with respect to the inside of the recess. As a result, the second film W2 is exposed on a bottom surface and a side surface of the recess Wa1. In addition, when the first film W1 is also deposited on the bottom surface of the recess Wa1 during Operation S101, the first film W1 deposited on the bottom surface is removed by etching or the like. Thereafter, by performing Operation S102 and subsequent operations, the third film W3 grows on the bottom surface and the side surface of the recess Wa1.

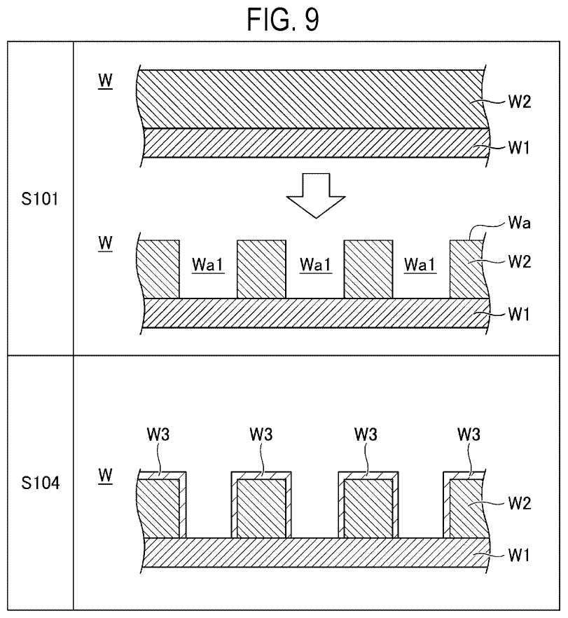

Next, a description of the case where the substrate W prepared in Operation S101 has the recess Wa1 on the substrate surface Wa, and the first film W1 is exposed only inside the recess Wa1 will be given with reference to FIGS. 9 to 11. As illustrated in FIGS. 9 to 11, the first film W1 is exposed at least on the bottom surface of the recess Wa1. In this case, by performing Operation S102 and subsequent operations, the third film W3 may be formed on a surface other than the bottom surface of the recess Wa1.

In Operation S101 of FIG. 9, first, the second film W2 is formed on the entire surface of the first film W1, and then a portion of the surface of the second film W2 is etched. As a result, the recess Wa1 is formed to penetrate a portion of the second film W2, and the first film W1 is exposed only on the bottom surface of the recess Wa1. Thereafter, by performing Operation S102 and subsequent operations, the third film W3 grows on the side surface of the recess Wa1 and the outside of the recess Wa1 (top surface of the protrusion).

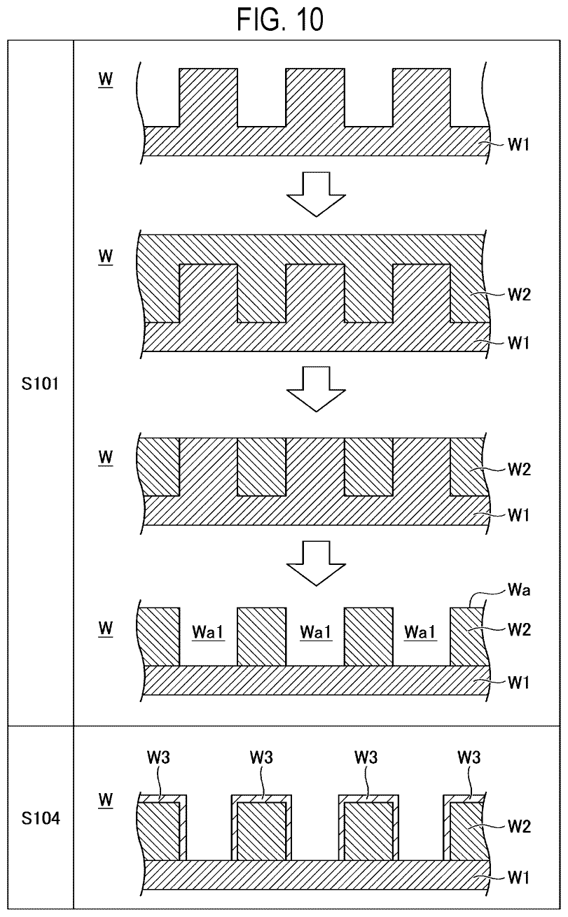

In Operation S101 of FIG. 10, first, a portion of the surface of the first film W1 is etched to form a recess on the surface of the first film W1. Then, the second film W2 that fills the recess is formed. Next, the second film W2 is processed by CMP or etching until the first film W1 is exposed. Lastly, the first film W1 is selectively etched with respect to the second film W2. As a result, the recess Wa1 is formed to penetrate a portion of the second film W2, and the first film W1 is exposed only on the bottom surface of the recess Wa1. Then, by performing Operation S102 and subsequent operations, the third film W3 grows on the side surface of the recess Wa1 and the outside of the recess Wa1 (top surface of the protrusion).

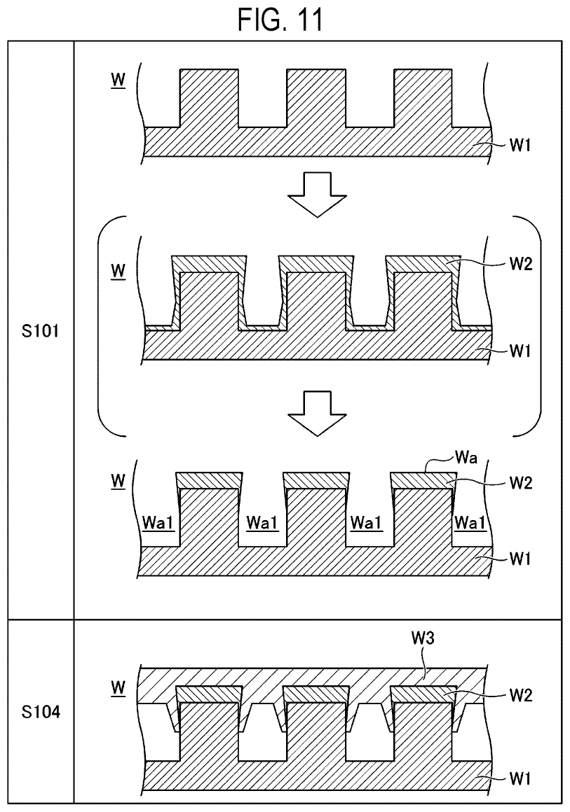

In Operation S101 of FIG. 11, first, a portion of the surface of the first film W1 is etched to form a recess on the surface of the first film W1. Next, the second film W2 is selectively formed on the outside of the recess (that is, on the top surface of the protrusion) with respect to the inside of the recess. As a result, the first film W1 is exposed on the bottom surface and the lower side surface of the recess Wa1. In addition, when the second film W2 is also deposited on the bottom surface of the recess Wa1 during Operation S101, the second film W2 deposited on the bottom surface is removed by etching or the like. Thereafter, by performing Operation S102 and subsequent operations, the third film W3 grows on the outside of the recess Wa1 (that is, the top surface of the protrusion) and on the upper side surface of the recess Wa1. The third film W3 may also confine an internal void (air gap) of the recess Wa1 as illustrated in FIG. 11.

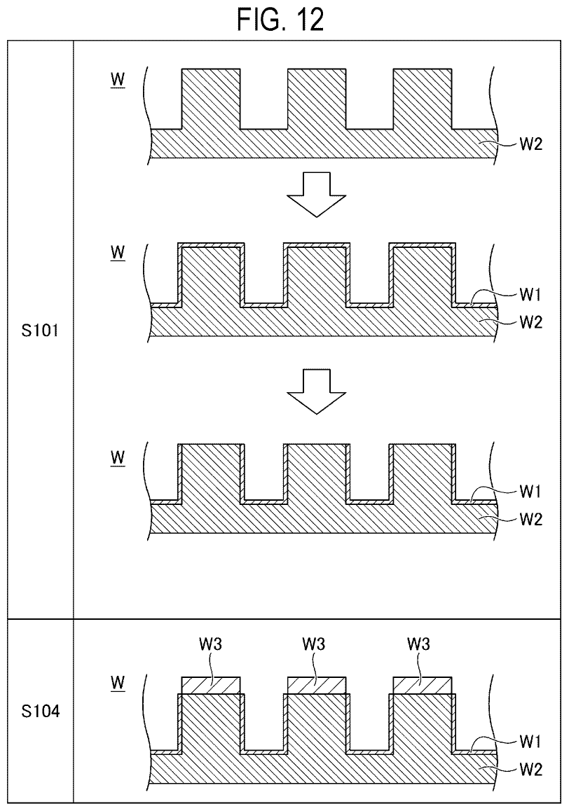

Next, a modified example of Operation S101 will be described with reference to FIG. 12. In Operation S101 of FIG. 12, first, the second film W2 having a concave-convex pattern is prepared. Next, the first film W1 is formed along the concave-convex pattern of the second film W2 over the entire second film W2 by an ALD method or a CVD method. Thereafter, a top surface of a protrusion of the second film W2 is exposed by CMP or etching. In this case, the first film W1 is left on the side surface and the bottom surface of the recess of the second film W2. Thereafter, by performing Operation S102 and subsequent operations, the third film W3 may be formed on the top surface of the protrusion.

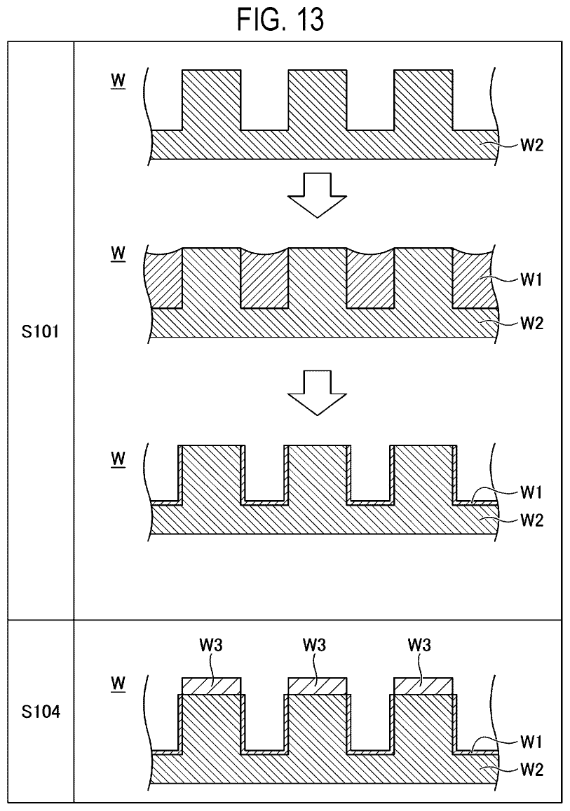

Next, still another modified example of Operation S101 will be described with reference to FIG. 13. In Operation S101 of FIG. 13, first, the second film W2 having a concave-convex pattern is prepared. Next, the first film W1 that fills a recess of the second film W2 is formed. The first film W1 is a liquid. The liquid is obtained by polymerizing, for example, B-containing molecules having an organic ligand such as tris(dimethylamino)borane (TDMAB: C₆H₁₈BN₃) using N₂ plasma or the like. Next, the liquid buried in the recess of the second film W2 is decomposed using 02 plasma or the like, so that the first film W1 remains on the side surface and the bottom surface of the recess of the second film W2. The top surface of the protrusion of the second film W2 remains exposed. Although not illustrated, the liquid buried in the recess of the second film W2 may be reformed using H₂ plasma or the like to form the first film W1 buried in the recess of the second film W2. Thereafter, by performing Operation S102 and subsequent operations, the third film W3 may be formed on the top surface of the protrusion.

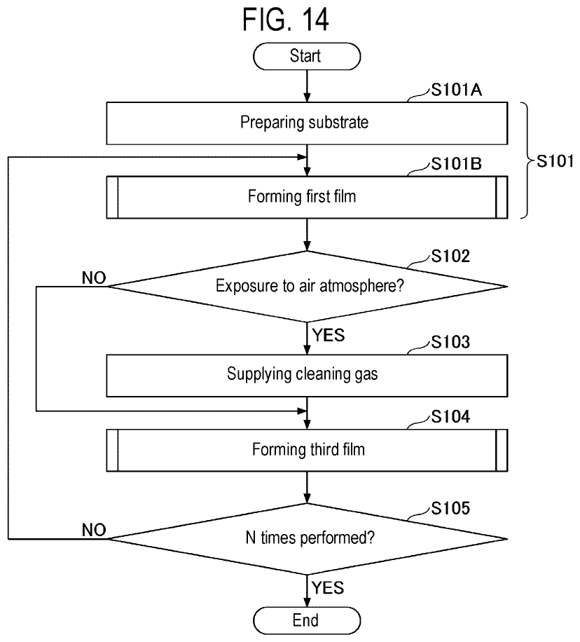

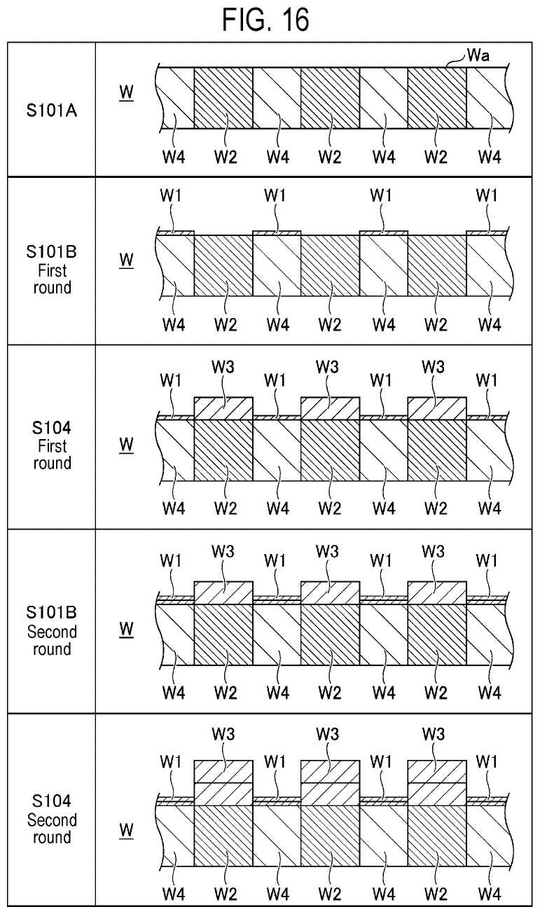

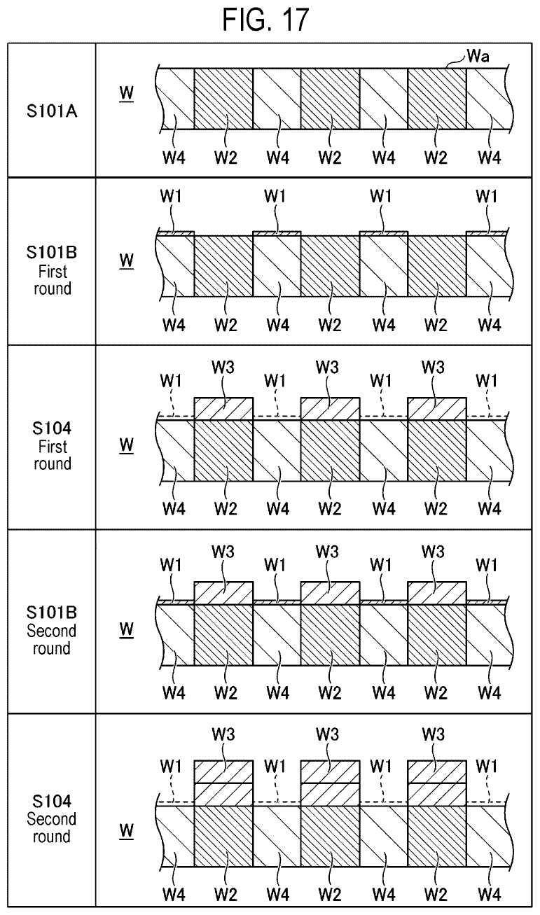

Next, a film formation method according to a modified example will be described with reference to FIGS. 14 to 17. Hereinafter, differences will be mainly described. As illustrated in FIGS. 16 and 17, Operation S101 may include preparing the substrate W having the second film W2 and a fourth film W4 made of a material different from that of the second film W2 in different regions of the surface Wa (Operation S101A), and selectively forming the first film W1 on the fourth film W4 with respect to the second film W2 (Operation S101B).

The fourth film W4 may be any film that may selectively form the first film W1 on the fourth film W4 with respect to the second film W2, and may be any one of an insulating film, a conductive film, and a semiconductor film. For example, an incubation time of the first film W1 with respect to the second film W2 may be longer than an incubation time of the first film W1 with respect to the fourth film W4. The first film W1 may be selectively formed using a difference in incubation time. The incubation time is a time difference from the start of the film formation process (for example, the start of the supply of the raw material gas or the reaction gas) to the actual start of film formation.

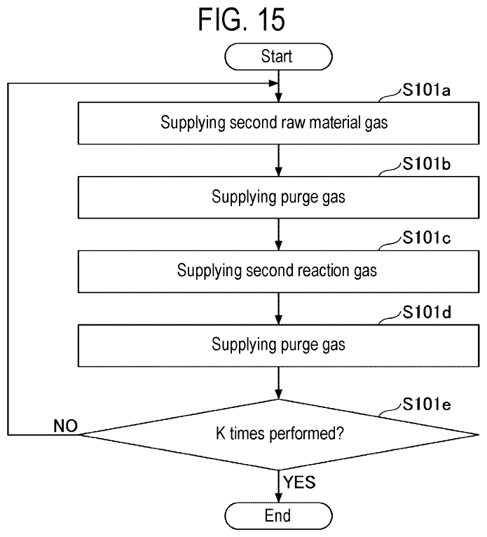

As illustrated in FIG. 15, Operation S101B includes, for example, Operations S101a to S101e. Alternatively, Operation S101B may include Operations S101a and S101c and may not include Operations S101b, S101d, and S101e. Hereinafter, Operations S101a to S101e will be described.

Operation S101a includes supplying a second raw material gas to the substrate surface Wa. The second raw material gas contains boron. The second raw material gas includes, for example, tris(dimethylamino)borane (TDMAB: C₆H₁₈BN₃). The second raw material gas may be supplied together with a dilution gas. The dilution gas is, for example, an Ar gas or a N₂ gas.

In addition, the second raw material gas is not limited to a gas containing TDMAB and may include, for example, diborane (B₂H₆), boron trichloride (BCl₃), boron trifluoride (BF₃), tris(ethylmethylamino)borane (C₉H₂₄BN₃), trimethylborane (C₃H₉B), or triethylborane (C₆H₁₅B), cyclotriborazane (B₃N₃H₆), or the like

Operation S101b includes supplying a purge gas to the substrate surface Wa. The purge gas purges an excessive second raw material gas that has not been adsorbed onto the substrate surface Wa in Operation S101a. As the purge gas, for example, a N₂ gas or a noble gas such as an Ar gas may be used.

Operation S101c includes supplying a second reaction gas to the substrate surface Wa. The second reaction gas forms the first film W1 on the substrate surface Wa by reacting with an adsorbate of the second raw material gas. The second reaction gas includes, for example, at least one of a nitrogen-containing gas, an oxygen-containing gas, or a reducing gas. The nitrogen-containing gas forms a boron nitride film by nitriding the second raw material gas. The nitrogen-containing gas includes, for example, NH₃, N₂, N₂H₄, or N₂H₂. The oxygen-containing gas forms a boron oxide film by oxidizing the second raw material gas. The oxygen-containing gas includes, for example, O₂, O₃, H₂O, NO, or N₂O. The reducing gas forms a boron film by reducing the second raw material gas. The reducing gas includes, for example, a H₂ gas, a SiH₄ gas, or a H₂S gas. The second reaction gas may be supplied together with a dilution gas such as an Ar gas.

Operation S101c may include plasmarizing the second reaction gas and may include supplying the plasmarized second reaction gas to the substrate surface Wa. By plasmarizing the second reaction gas, the formation of the first film W1 may be promoted.

Alternatively, the second reaction gas may be supplied not only in Operation S101c but also in all of Operations S101a to S101d. However, the plasmarization of the second reaction gas is performed only in Operation S101c. This is because the reaction of the second raw material gas with the adsorbate on the substrate surface Wa is promoted by plasmarizing the second reaction.

Operation S101d includes supplying the purge gas to the substrate surface Wa. The purge gas purges the excessive second reaction gas that has not reacted with the substrate surface Wa in Operation S101c. As the purge gas, for example, a N₂ gas or a noble gas such as an Ar gas may be used.

In Operation S101e, it is determined whether or not Operations S101a to S101d have been performed K times (where K is an integer equal to or greater than). K may be an integer equal to or greater than 2, and Operations S101a to S101d may be repeatedly performed. The thickness of the first film W1 may be increased.

When it is determined that the execution number of times of Operations S101a to S101d is less than K times (“NO” in Operation S101e), the thickness of the first film W1 is less than a target value. Thus, Operations S101a to S101d are performed again. The first film W1 inhibits the formation of the third film W3 in Operation S104 and may be formed thickly enough not to expose the fourth film W4. Unlike the first film W1, the fourth film W4 contains substantially no boron.

It is considered that the first film W1 becomes a film when nuclei grow on the surface of the fourth film W4 and adjacent nuclei come into contact with each other. It is considered that portions in which the fourth film W4 is exposed exist in a dispersed manner until the nuclei has a sufficient size. Therefore, the thickness of the first film W1 may be 10 Å or more. When the thickness of the first film W1 is less than 10 Å, it is considered that the portions in which the fourth film W4 is exposed exist and the effect of inhibiting the formation of the third film W3 is reduced.

On the other hand, when the execution number of times of Operations S101a to S101d reaches K times (“YES” in Operation S101e), the thickness of the first film W1 is determined to reach the target value. Thus, Operation S101 ends.

The method of forming the first film W1 illustrated in FIG. 15 is an ALD method but may also be a CVD method. In the ALD method, the supply of the second raw material gas and the supply of the second reaction gas are alternately performed. On the other hand, in the CVD method, the supply of the second raw material gas and the supply of the second reaction gas are simultaneously performed.

Alternatively, the first film W1 may be a molecular film in which molecules are chemically or physically adsorbed to each other. The molecules are supplied to the substrate surface in a gaseous state. The gas has a functional group that tends to be selectively adsorbed onto a desired region of the substrate surface among the molecules and also includes boron B among the molecules. The first film W1 may be a film in which the adsorbed molecules are decomposed by the heat of the substrate W.

Operation S105 (see FIG. 14) includes determining whether or not a series of processes has been performed N times (where N is an integer equal to or greater than 1). The series of processes includes the formation of the first film W1 (Operation S101B) and the formation of the third film W3 (Operation S104). This series of processes is also called a first cycle. When it is determined that the execution number of times of the first cycle is less than N times (“NO” in Operation S105), the thickness of the third film W3 is insufficient. Thus, the first cycle is performed again. On the other hand, when it is determined that the execution number of times of the first cycle reaches N times (“YES” in Operation S105), the process ends. N is specifically an integer greater than or equal to 2. When N is an integer greater than or equal to 2, the film thickness of the third film W3 may be increased while supplementing the first film W1.

Next, a film formation method when N is an integer equal to or greater than 2 will be described with reference to FIGS. 16 and 17. When N is an integer equal to or greater than 2, the first cycle is repeated multiple times.

A second round of Operation S101B and subsequent operations include selectively forming the first film W1 again on the first film W1 with respect to the third film W3 (see FIG. 16). In addition, in a first round of Operation S104 (the formation of the third film W3), there are cases in which the first film W1 becomes thinner and cases in which the first film W1 disappears (see FIG. 17). When the first film W1 disappears, the second round of Operation S101B and subsequent operations includes selectively forming the first film W1 again on the fourth film W4 instead of the first film W1 (see FIG. 17).

The second round of Operation S104 and subsequent operations includes selectively forming the third film W3 on the third film W3 with respect to the first film W1.

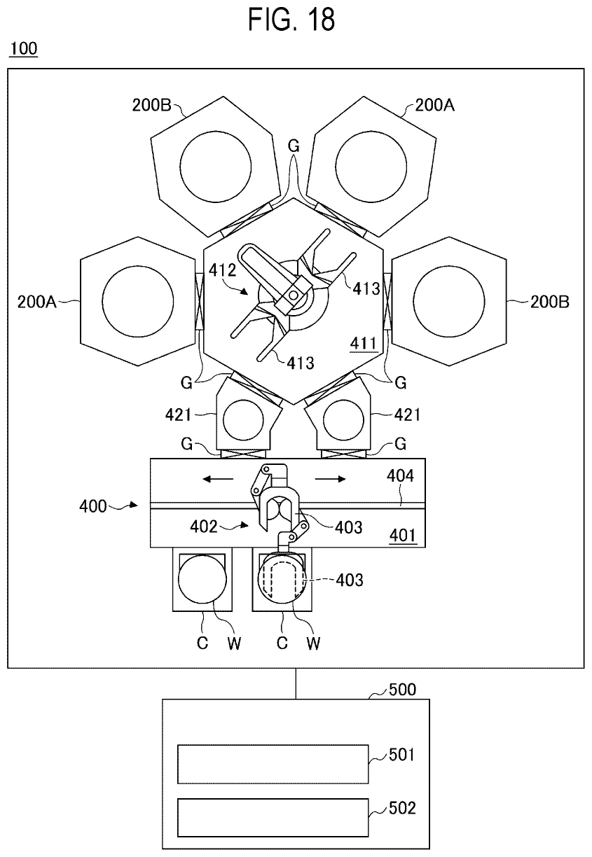

Next, a film forming apparatus 100 that executes the above-described film formation method will be described with reference to FIG. 18. As illustrated in FIG. 18, the film formation apparatus 100 includes a first processor 200A, a second processor 200B, a transferer 400, and a controller 500. The first processor 200A performs Operation S103 in FIG. 1. The second processor 200B performs Operation S104 in FIG. 1. The first processor 200A and the second processor 200B may have the same or different structures.

Further, the first processor 200A may perform both Operations S103 and S104 in FIG. 1. Further, the first processor 200A may perform Operation S101B in FIG. 14, and the second processor 200B may perform Operation S104 in FIG. 14. When the first processor 200A and the second processor 200B are connected to a second transfer chamber 411 and an internal atmosphere of the second transfer chamber 411 is a vacuum atmosphere, Operation S103 in FIG. 14 may be omitted.

The transferer 400 transfers the substrate W to the first processor 200A and the second processor 200B. The transferer 400 includes a first transfer chamber 401 and a first transfer mechanism 402. An internal atmosphere of the first transfer chamber 401 is an air atmosphere. The first transfer mechanism 402 is provided inside the first transfer chamber 401. The first transfer mechanism 402 includes an arm 403 that holds the substrate W and travels along a rail 404. The rail 404 extends in an arrangement direction of a carrier C.

Further, the transferer 400 includes a second transfer chamber 411 and a second transfer mechanism 412. An internal atmosphere of the second transfer chamber 411 is a vacuum atmosphere. The second transfer mechanism 412 is provided inside the second transfer chamber 411. The second transfer mechanism 412 includes an arm 413 that holds the substrate W. The arm 413 is arranged to be movable in a vertical direction and a horizontal direction and rotatable around a vertical axis. The first processor 200A and the second processor 200B are connected to the second transfer chamber 411 via different gate valves G.

In addition, the transferer 400 includes a load lock chamber 421 provided between the first transfer chamber 401 and the second transfer chamber 411. An internal atmosphere of the load lock chamber 421 is switched between a vacuum atmosphere and an air atmosphere by a pressure regulating mechanism which is not illustrated. Thus, the interior of the second transfer chamber 411 may always be maintained in the vacuum atmosphere. In addition, a gas may be suppressed from flowing into the second transfer chamber 411 from the first transfer chamber 401. Gate valves G are provided between the first transfer chamber 401 and the load lock chamber 421, and between the second transfer chamber 411 and the load lock chamber 421.

The controller 500 is, for example, a computer, and includes an operator 501 such as a central processing unit (CPU) 501, and a storage 502 such as a memory. The storage 502 stores a program for controlling various processes executed in the film formation apparatus 100. The controller 500 controls the operation of the film formation apparatus 100 by causing the CPU 501 to execute the program stored in the storage 502. The controller 500 controls the first processor 200A, the second processor 200B, and the transferer 400 to perform the above-described film formation method.

Next, the operation of the film formation apparatus 100 will be described. First, the first transfer mechanism 402 takes the substrate 1 out of the carrier C, transfers the same to the load lock chamber 421, and is withdrawn from the load lock chamber 421. Subsequently, the internal atmosphere of the load lock chamber 421 is switched from the air atmosphere to the vacuum atmosphere. Thereafter, the second transfer mechanism 412 takes the substrate W out of the load lock chamber 421 and transfers the same to the first processor 200A.

Thereafter, the first processor 200A performs Operations S103 in FIG. 1. Subsequently, the second transfer mechanism 412 takes the substrate W out of the first processor 200A and transfers the same to the second processor 200B. During that time, the substrate surface Wa may be protected in the vacuum atmosphere to be suppressed from being contaminated by an organic compound in the air.

Next, the second processor 200B performs Operation S104 in FIG. 1. Next, the second transfer mechanism 412 takes the substrate W out of the second processor 200B, transfers the same to the load lock chamber 421, and is withdrawn from the load lock chamber 421. Thereafter, the internal atmosphere of the load lock chamber 421 is switched from the vacuum atmosphere to the air atmosphere. Thereafter, the first transfer mechanism 402 takes the substrate W out of the load lock chamber 421 and accommodates the same in the carrier C. Then, processing of the substrate W ends.

In addition, the formation of the first film W1 (Operation S101B in FIG. 14) and the formation of the third film W3 (Operation S104 in FIG. 14) may be performed in different film forming apparatuses. As the carrier C that transfers the substrate W from one film forming apparatus to another film forming apparatus, a carrier C whose internal atmosphere is a vacuum atmosphere or an inert gas atmosphere may be used. In this case, the determination result of Operation S102 in FIG. 14 is “NO”. Therefore, in this case, Operation S104 is performed without performing Operation S103.

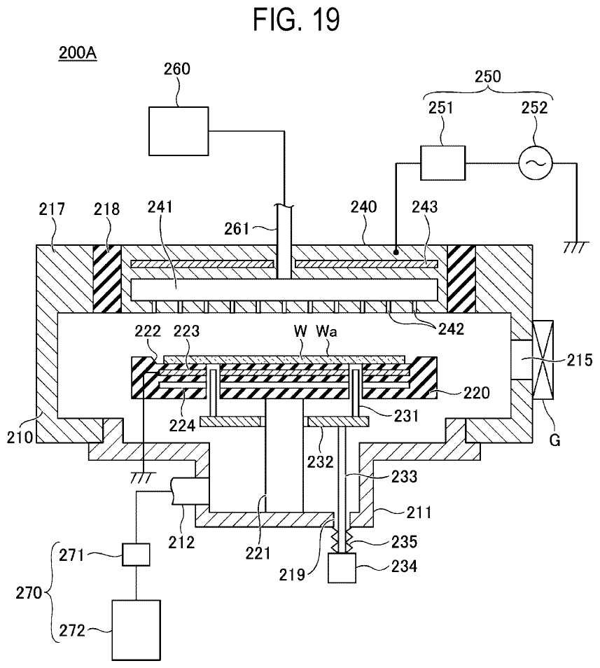

Next, the first processor 200A will be described with reference to FIG. 19. The second processor 200B is similar in configuration to the first processor 200A, and therefore, illustration and description thereof will be omitted.

The first processor 200A includes a substantially cylindrical airtight processing container 210. An exhaust chamber 211 is provided at a central portion of a bottom wall of the processing container 210. The exhaust chamber 211 has, for example, a substantially cylindrical shape that protrudes downward. An exhaust pipe 212 is connected to the exhaust chamber 211, for example, on a side surface of the exhaust chamber 211.

An exhaust source 272 is connected to the exhaust pipe 212 via a pressure regulator 271. The pressure regulator 271 includes, for example, a pressure regulating valve such as a butterfly valve. The exhaust pipe 212 is configured to depressurize the interior of the processing container 210 by the exhaust source 272. The pressure regulator 271 and the exhaust source 272 constitute a gas discharge mechanism 270 configured to discharge a gas in the processing container 210.

A transfer port 215 is provided in the side surface of the processing container 210. The transfer port 215 is opened and closed by a gate valve G. The substrate W is loaded and unloaded between the interior of the processing container 210 and the second transfer chamber 411 (see FIG. 18) via the transfer port 215.

A stage 220, which is a holder for holding the substrate W, is provided inside the processing container 210. The stage 220 holds the substrate W horizontally, with the substrate surface Wa oriented upward. The stage 220 is formed in a substantially circular shape in a plan view and is supported by a support member 221. A substantially circular recess 222 is formed in a surface of the stage 220. The substrate W having a diameter of, for example, 300 mm, is placed on the recess 222. The recess 222 has an inner diameter slightly larger than the diameter of the substrate W. The depth of the recess 222 is substantially the same as, for example, the thickness of the substrate W. The stage 220 is made of, for example, a ceramic material such as aluminum nitride (AlN). The stage 220 may also be made of a metal material such as nickel (Ni). Instead of the recess 222, a guide ring that guides the substrate W may also be provided at a peripheral edge portion of the surface of the stage 220.

For example, a grounded lower electrode 223 is embedded in the stage 220. A heating mechanism 224 is embedded below the lower electrode 223. The heating mechanism 224 heats the substrate W placed on the stage 220 to a set temperature by being supplied with power from a power source (not illustrated) based on a control signal from the controller 500 (see FIG. 18). When the stage 220 is entirely made of a metal, the stage 220 itself functions as a lower electrode. Thus, the lower electrode 223 does not need to be embedded in the stage 220. The stage 220 is provided with a plurality of (for example, three) lifting pins 231 for holding and lifting the substrate W placed on the stage 220. A material of the lifting pins 231 may be, for example, ceramic such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between an opening 219 for the lifting shaft 233, which is formed in a lower surface of the exhaust chamber 211, and the lifting mechanism 234. The support plate 232 may be shaped to be raised and lowered without interfering with the support member 221 of the stage 220. The lifting pins 231 are configured to be raised and lowered between a position above the surface of the stage 220 and a position below the surface of the stage 220 by the lifting mechanism 234.

A gas supplier 240 is provided on a ceiling wall 217 of the processing container 210 via an insulating member 218. The gas supplier 240 constitutes an upper electrode and faces the lower electrode 223. A radio-frequency power source 252 is connected to the gas supplier 240 via a matcher 251. By supplying a radio-frequency power of 100 kHz to 40 MHz, specifically, 450 kHz to 100 MHz, from the radio-frequency power source 252 to the upper electrode (the gas supplier 240), a radio-frequency electric field is generated between the upper electrode (the gas supplier 240) and the lower electrode 223 to generate capacitively coupled plasma. A plasma generator 250 that generates plasma includes the matcher 251 and the radio-frequency power source 252. The plasma generator 250 may be a plasma generator that generates other plasma, such as inductively coupled plasma, without being limited to the capacitively coupled plasma. In a process in which plasma is not generated, the gas supplier 240 does not need to constitute the upper electrode, and the lower electrode 223 is also unnecessary.

The gas supplier 240 includes a hollow gas supply chamber 241. A plurality of holes 242 for dispersedly supplying a processing gas into the processing container 210 may be arranged evenly in a lower surface of the gas supply chamber 241. In the gas supplier 240, a heating mechanism 243 is embedded, for example, above the gas supply chamber 241. The heating mechanism 243 is heated to a set temperature by being supplied with power from the power source (not illustrated) based on the control signal from the controller 500.

A gas supply mechanism 260 is connected to the gas supply chamber 241 via a gas supply path 261. The gas supply mechanism 260 supplies a gas used in the processes of FIG. 1 or 14 via the gas supply path 261. Although not illustrated, the gas supply mechanism 260 includes an individual pipe, an opening/closing valve provided in the individual pipe, and a flow rate controller provided in the individual pipe, for each type of gas. When the individual pipe is opened by the opening/closing valve, a gas is supplied from a gas source to the gas supply path 261. A supply amount of the gas is controlled by the flow rate controller. On the other hand, when the individual pipe is closed by the opening/closing valve, the supply of the gas from the gas source to the gas supply path 261 is stopped.

### EXAMPLES AND COMPARATIVE EXAMPLES

Hereinafter, Examples and Comparative Examples will be described.

### Example 1

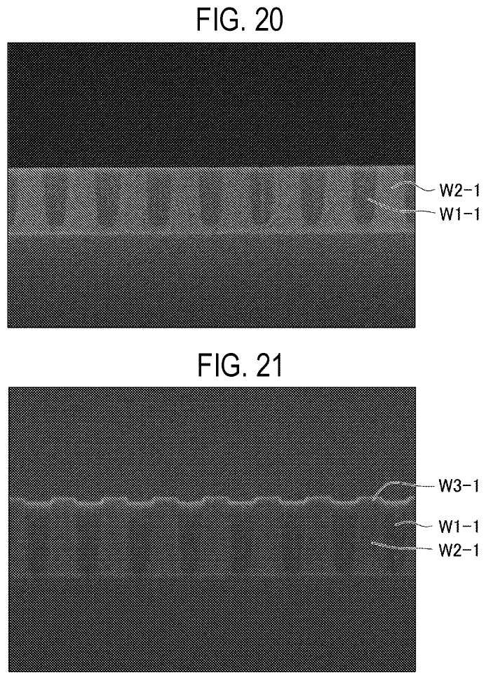

In Example 1, as illustrated in FIG. 20, a substrate having a BN film W1-1 and a SiO film W2-1 on a substrate surface exposed to an air atmosphere was prepared, and Operations S103 and S104 in FIG. 1 were performed under processing conditions shown in Table 1. In Example 1, the first film was the BN film W1-1, the second film was the SiO film W2-1, the cleaning gas was the O₂ gas, the raw material gas was the TiCl₄ gas, the reaction gas was the NH₃ gas, and the third film was a TiN film W3-1.

TABLE 1

| | | | Time | Supplied | | Temperature | Number |
|---|---|---|---|---|---|---|---|
| | Operation | | (sec) | Gas | RF | (degrees C.) | of Times |
| Example 1 | S103 | S103a | 10 | O₂ + Ar | OFF | 350 | 1 |
| | | S103b | 20 | O₂ + Ar | ON | | |
| | | S103c | 10 | Ar | OFF | | |
| | S104 | S104a | 2 | TiCl₄ + Ar | OFF | 350 | 100 |
| | | S104b | 5 | Ar | OFF | | |
| | | S104f | 2 | NH₃ + Ar | OFF | | |
| | | S104c | 2 | NH₃ + Ar | ON | | |
| | | S104d | 5 | Ar | OFF | | |

In Table 1, “ON” in the item “RF” means that the gas was plasmarized by the radio frequency power. “OFF” in the item “RF” means that the gas was not plasmarized. The same applies to Tables 2, 3, and 4 below. As shown in Table 1, the gas was plasmarized in Operations S103b and S104c.

As shown in Table 1, in Operation S103, Operations S103a, S103b, and S103c were sequentially performed once. Operation S103a performed prior to Operation S103b is an operation of stabilizing the flow rate of the cleaning gas (the O₂ gas in Example 1) supplied to the substrate surface in Operation S103b. Operation S103b is an operation of supplying the cleaning gas to the substrate surface. Operation S103c is an operation of replacing the cleaning gas remaining on the substrate surface with an inert gas.

As shown in Table 1, in Operation S104, Operations S104a, S104b, S104f, S104c, and S104d were sequentially repeatedly performed 100 times (where L illustrated in FIG. 2 is 100). Except for Operation S104f, the contents of Operations S104a, S104b, and S104c are as already described. Operation S104f performed prior to Operation S104c is an operation of stabilizing the flow rate of the reaction gas used in Operation S104c.

In Example 1, from immediately after Operation S103 to immediately before Operation S104, the substrate surface was protected in a vacuum atmosphere without exposing the substrate surface to the air atmosphere. As a result, as illustrated in FIG. 21, the TiN film W3-1 was selectively formed on the SiO film W2-1 with respect to the BN film W1-1. The TiN film W3-1 was mostly not formed on the surface of the BN film W1-1.

As a result of analyzing a surface composition of the BN film W1-1 by time-of-flight secondary ion mass spectrometry (TOF-SIMS) immediately before and immediately after Operation S103, the content of carbon (C) was reduced immediately after Operation S103 relative to immediately before Operation S103. Since the content of carbon was reduced, it may be appreciated that the organic compound was removed by performing Operation S103.

### Comparative Example 2

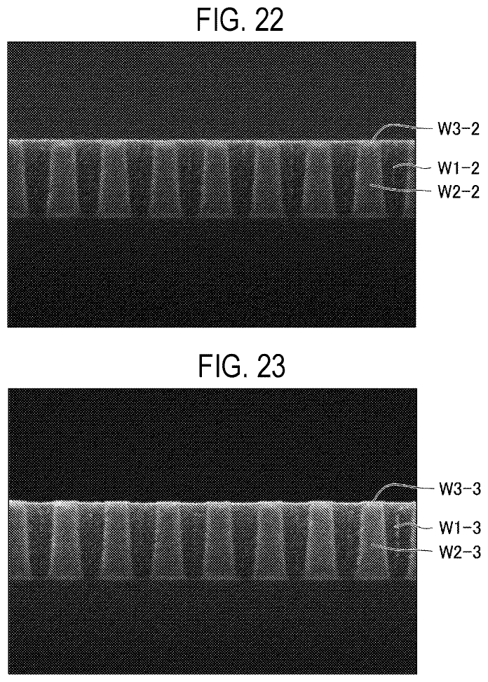

In Comparative Example 2, the substrate was processed in the same manner as in Example 1, except that Operation S103 was not performed. As a result, as illustrated in FIG. 22, a TiN film W3-2 was formed on both surfaces of a BN film W1-2 and a SiO film W2-2 with substantially the same thickness.

From the results of Example 1 and Comparative Example 2, it may be appreciated that, in order for the BN film to inhibit the formation of the TiN film, it is important to remove the organic compound in advance.

### Comparative Example 3

In Comparative Example 3, the substrate was processed in the same manner as in Example 1, except that the substrate surface was exposed to the air atmosphere for 40 minutes after performing Operation S103 and before performing Operation S104. As a result, as illustrated in FIG. 23, it was observed that a BN film W1-3 inhibited the formation of a TiN film W3-3 and there was a difference in the film thickness of the TiN film W3-3 between the surface of the BN film W1-3 and the surface of a SiO film W2-3. However, the TiN film W3-3 was formed on both surfaces of the BN film W1-3 and the SiO film W2-3.

From the results of Example 1 and Comparative Example 3, it may be appreciated that, in order for the BN film to sufficiently inhibit the formation of the TiN film, it is important not to expose the substrate surface to the air atmosphere from immediately after removing the organic compound to immediately before forming of the TiN film.

### Example 4

In Example 4, the substrate was processed in the same manner as in Example 1, except that Operations S103 and S104 in FIG. 1 were performed under the processing conditions shown in Table 2. In Example 4, the first film was a BN film W1-4, the second film was a SiO film W2-4, the cleaning gas was the O₂ gas, the raw material gas was the TiCl₄ gas, the reaction gas was the O₃ gas, and the third film was a TiO film W3-4. An ozone generator configured to generate the O₃ gas was provided in an 02 gas supply path.

TABLE 2

| | | | Time | | | Temperature | Number |
|---|---|---|---|---|---|---|---|
| | Operation | | (sec) | Supplied Gas | RF | (degrees C.) | of Times |
| Example 4 | S103 | S103a | 10 | O₂ + Ar | OFF | 350 | 1 |
| | | S103b | 20 | O₂ + Ar | ON | | |
| | | S103c | 10 | Ar | OFF | | |
| | S104 | S104a | 1,200 | TiCl₄ + O₂ + O₃ + Ar | OFF | 350 | 1 |
| | | S104c | | | | | |

As illustrated in Table 2, in Operation S103, Operations S103a, S103b, and S103c were sequentially performed once in the same manner as in Example 1. As illustrated in Table 2, unlike Example 1, in Operation S104, Operations S104a and S104c were performed simultaneously once. As shown in Table 2, the gas was plasmarized in Operation S103b, whereas the gas was not plasmarized in Operation S104c.

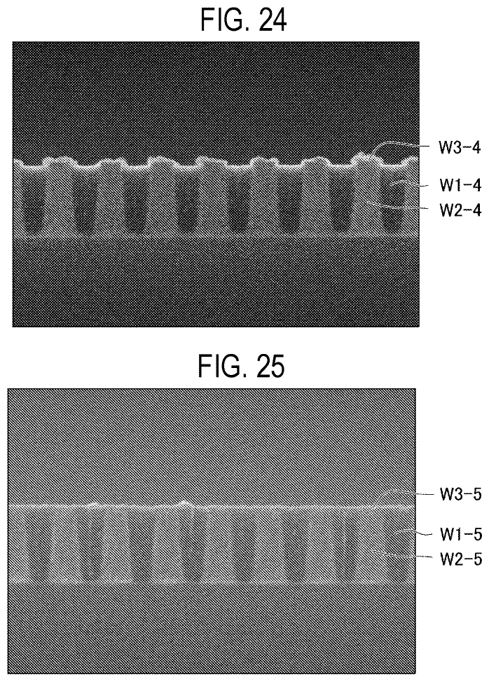

In Example 4, from immediately after Operation S103 to immediately before Operation S104, the substrate surface was protected in the vacuum atmosphere without exposing the substrate surface to the air atmosphere. As a result, as illustrated in FIG. 24, the TiO film W3-4 was selectively formed on the SiO film W2-4 with respect to the BN film W1-4. The TiO film W3-4 was mostly not formed on the surface of the BN film W1-4.

### Comparative Example 5

In Comparative Example 5, the substrate was processed in the same manner as in Example 4, except that Operation S103 was not performed. As a result, as illustrated in FIG. 25, a TiO film W3-5 was formed on both surfaces of a BN film W1-5 and a SiO film W2-5 with substantially the same thickness.

From the results of Example 4 and Comparative Example 5, it may be appreciated that, in order for the BN film to inhibit the formation of the TiO film, it is important to remove the organic compound in advance.

### Comparative Example 6

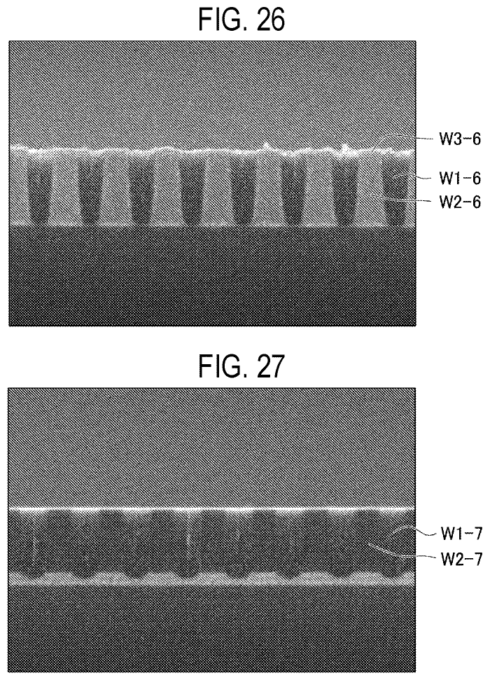

In Comparative Example 6, the substrate was processed in the same manner as in Example 4, except that the substrate surface was exposed to the air atmosphere for 5 minutes after performing Operation S103 and before performing Operation S104. As a result, as illustrated in FIG. 26, it was observed that a BN film W1-6 inhibited the formation of a TiO film W3-6 and there is a difference in the film thickness of the TiO film W3-6 between the surface of the BN film W1-6 and the surface of a SiO film W2-6. However, the TiO film W3-6 was formed on both surfaces of the BN film W1-6 and the SiO film W2-6.

From the results of Example 4 and Comparative Example 6, it may be appreciated that, in order for the BN film to sufficiently inhibit the formation of the TiO film, it is important not to expose the substrate surface to the air atmosphere from immediately after removing the organic compound to immediately before forming the TiO film.

### Example 7

In Example 7, as illustrated in FIG. 27, a substrate having a BN film W1-7 and a Si film W2-7 on a substrate surface exposed to an air atmosphere was prepared, and Operations S103 and S104 in FIG. 1 were performed under the processing conditions shown in Table 3. In Example 7, the first film was the BN film W1-7, the second film was the Si film W2-7 (specifically, an amorphous Si film), the cleaning gas was the O₂ gas, the raw material gas was the Si₂Cl₆ gas, the reaction gas was the NH₃ gas, and the third film was a SiN film W3-7.

TABLE 3

| | | | Time | Supplied | | Temperature | Number |
|---|---|---|---|---|---|---|---|
| | Operation | | (sec) | Gas | RF | (degrees C.) | of Times |
| Example 7 | S103 | S103a | 10 | O₂ + Ar | OFF | 350 | 1 |
| | | S103b | 20 | O₂ + Ar | ON | | |
| | | S103c | 10 | Ar | OFF | | |
| | S104 | S104a | 2 | Si₂Cl₆ + Ar | OFF | 350 | 300 |
| | | S104b | 5 | Ar | OFF | | |
| | | S104f | 2 | NH₃ + Ar | OFF | | |
| | | S104c | 2 | NH₃ + Ar | OFF | | |
| | | S104d | 5 | Ar | OFF | | |

As shown in Table 3, in Operation S103, Operations S103a, S103b, and S103c were sequentially performed once in the same manner as in Example 1. As illustrated in Table 3, in Operation S104, Operations S104a, S104b, S104f, S104c, and S104d were sequentially performed 300 times (where L illustrated in FIG. 2 is 300). As shown in Table 3, the gas was plasmarized in Operation S103b, whereas the gas was not plasmarized in Operation S104c.

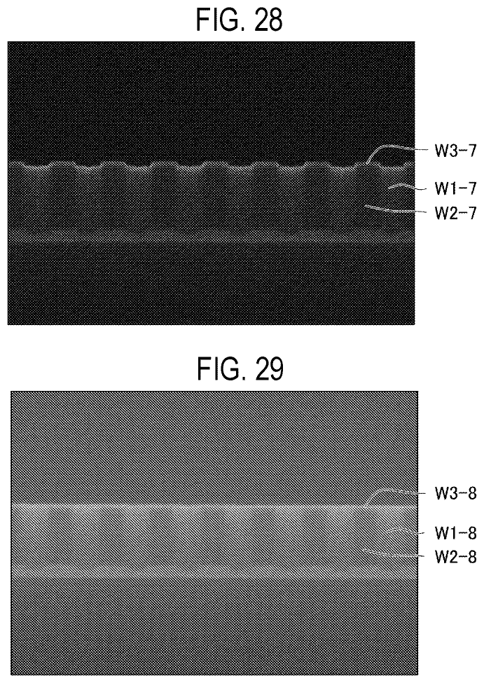

In Example 7, from immediately after Operation S103 to immediately before Operation S104, the substrate surface was protected in the vacuum atmosphere without exposing the substrate surface to the air atmosphere. As a result, as illustrated in FIG. 28, a SiN film W3-7 was selectively formed on a Si film W2-7 with respect to the BN film W1-7. The SiN film W3-7 was mostly not formed on the surface of the BN film W1-7.

### Comparative Example 8

In Comparative Example 8, the substrate was processed in the same manner as in Example 7, except that Operation S103 was not performed. As a result, as illustrated in FIG. 29, a SiN film W3-8 was formed on both surfaces of a BN film W1-8 and a Si film W2-8 with substantially the same thickness.

From the results of Example 7 and Comparative Example 8, it may be appreciated that, in order for the BN film to inhibit the formation of the SiN film, it is important to remove the organic compound in advance.

### Example 9

In Example 9, the substrate was processed in the same manner as in Example 1, except that Operations S103 and S104 in FIG. 1 were performed under the processing conditions shown in Table 4. In Example 9, the first film was a BN film W1-9, the second film was a SiO film W2-9, the cleaning gas was the O₂ gas, the raw material gas was the TiCl₄ gas, the reaction gas was the H₂ gas, and the third film was a Ti film W3-9.

TABLE 4

| | | | Time | Supplied | | Temperature | Number |
|---|---|---|---|---|---|---|---|
| | Operation | | (sec) | Gas | RF | (degrees C.) | of Times |
| Example 9 | S103 | S103a | 10 | O₂ + Ar | OFF | 450 | 1 |
| | | S103b | 20 | O₂ + Ar | ON | | |
| | | S103c | 10 | Ar | OFF | | |
| | S104 | S104a | 2 | TiCl₄ + Ar | OFF | 450 | 300 |
| | | S104b | 5 | Ar | OFF | | |
| | | S104f | 1 | H₂ + Ar | OFF | | |
| | | S104c | 1 | H₂ + Ar | ON | | |
| | | S104d | 5 | Ar | OFF | | |

As shown in Table 4, in Operation S103, Operations S103a, S103b, and S103c were sequentially performed once in the same manner as in Example 1. As illustrated in Table 4, in Operation S104, Operations S104a, S104b, S104f, S104c, and S104d were sequentially performed 300 times (where L illustrated in FIG. 2 is 300). As shown in Table 4, the gas was plasmarized in Operations S103b and S104c.

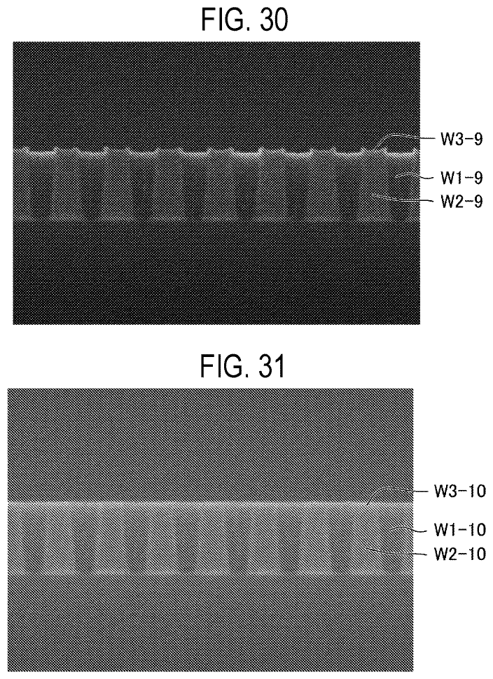

In Example 9, from immediately after Operation S103 to immediately before Operation S104, the substrate surface was protected in the vacuum atmosphere without exposing the substrate surface to the air atmosphere. As a result, as illustrated in FIG. 30, the Ti film W3-9 was selectively formed on the SiO film W2-9 with respect to the BN film W1-9. The Ti film W3-9 was mostly not formed on the surface of the BN film W1-9.

### Comparative Example 10

In Comparative Example 10, the substrate was processed in the same manner as in Example 9, except that Operation S103 was not performed. As a result, as illustrated in FIG. 31, a Ti film W3-10 was formed on both surfaces of a BN film W1-10 and a SiO film W2-10 with substantially the same thickness.

From the results of Example 9 and Comparative Example 10, it may be appreciated that, in order for the BN film to inhibit the formation of the Ti film, it is important to remove the organic compound in advance.

According to one aspect of the present disclosure, it is possible to selectively form a third film on a second film made of a material different from that of a first film with respect to the first film containing boron.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modification as would fall within the scope and spirit of the disclosures.

What is claimed is:

1. A film formation method, comprising:
preparing a substrate having a first film containing boron and a second film made of a material different from a material of the first film in different regions of a surface of the substrate;
supplying a cleaning gas to the surface of the substrate to remove an organic compound;
selectively forming a third film on the second film with respect to the first film from which the organic compound has been removed; and
protecting the surface of the substrate in at least one of a vacuum atmosphere or an inert atmosphere from immediately after removing the organic compound to immediately before forming the third film without exposing the surface of the substrate to an air atmosphere,
wherein the forming the third film includes forming the third film containing an element by alternately or simultaneously supplying a raw material gas, which contains halogen and the element other than the halogen, and a reaction gas, which reacts with an adsorbate of the raw material gas, to the surface of the substrate.

2. The film formation method of claim 1, wherein the preparing the substrate includes selectively forming the first film on a fourth film made of a material different from the material of the second film with respect to the second film.

3. A film formation method, comprising:
preparing a substrate having a second film and a fourth film formed of a material different from a material of the second film in different regions of a surface of the substrate;
selectively forming a first film containing boron on the fourth film with respect to the second film;
selectively forming a third film on the second film with respect to the first film; and
protecting the surface of the substrate in at least one of a vacuum atmosphere or an inert atmosphere from immediately after forming the first film to immediately before forming the third film without exposing the surface of the substrate to an air atmosphere,
wherein the forming the third film includes forming the third film containing an element by alternately or simultaneously supplying a raw material gas, which contains halogen and the element other than the halogen, and a reaction gas, which reacts with an adsorbate of the raw material gas, to the surface of the substrate.

4. The film formation method of claim 2, further comprising:
selectively forming the first film again on the first film or the fourth film with respect to the third film after forming the third film; and
selectively forming the third film again on the third film with respect to the first film that has been formed again.

5. The film formation method of claim 1, wherein the reaction gas is a gas containing nitrogen.

6. The film formation method of claim 1, wherein the reaction gas is a gas containing hydrogen.

7. The film formation method of claim 1, wherein the reaction gas is a gas containing oxygen.

8. The film formation method of claim 1, wherein the second film contains substantially no boron.

9. The film formation method of claim 1, wherein the surface of the substrate including the first film and the second film before forming the third film has a recess, and
wherein the first film is exposed only inside the recess, and is exposed at least on a bottom surface of the recess.

10. The film formation method of claim 1, wherein the surface of the substrate including the first film and the second film before forming the third film has a recess, and
wherein the second film is exposed only inside the recess, and is exposed at least on a bottom surface of the recess.

11. The film formation method of claim 1, wherein the element includes a metal element.

12. The film formation method of claim 1, wherein the element includes a transition metal element.

13. The film formation method of claim 1, wherein the element includes a semiconductor element.

14. The film formation method of claim 1, wherein the forming the third film includes alternately supplying the raw material gas and the reaction gas, and plasmarizing the reaction gas to supply a plasmarized reaction gas.

15. The film formation method of claim 1, wherein the forming the third film includes performing, once or more, a process of sequentially supplying the raw material gas containing a first element as the element, supplying the raw material gas containing a second element different from the first element as the element, and supplying the reaction gas.

16. The film formation method of claim 1, wherein the forming the third film includes performing, once or more, a process of sequentially supplying the raw material gas containing a first element as the element and supplying the reaction gas, and performing, once or more, a process of sequentially supplying the raw material gas containing a second element different from the first element as the element and supplying the reaction gas.

17. A film formation apparatus, comprising:
a processing container in which the substrate is accommodated;
a holder configured to hold the substrate inside the processing container;
a supplier configured to supply a gas to a surface of the substrate held by the holder; and
a controller configured to control the supplier,
wherein the controller performs control to execute the film formation method of claim 1.
